(19) United States
(12) Patent Application Publication
(10) Pub. No.: US 2025/0342298 A1
(43) Pub. Date: Nov. 6, 2025

(54) METHOD AND SYSTEM FOR OPERATING COMPLEX DATA PACKET CAPABLE OF BEING DYNAMICALLY DEFINED

(71) Applicant: Jinan Xinyu software technology co. Ltd., Jinan, Shandong (CN)

(72) Inventors: Min Yi, Jinan, Shandong (CN); Yunzhao Yang, Jinan, Shandong (CN); Min Cheng, Jinan, Shandong (CN); Chuanqiang Shen, Jinan, Shandong (CN); Xingwan Xia, Jinan, Shandong (CN); Ming Wei, Jinan, Shandong (CN); Tianhao Yi, Jinan, Shandong (CN)

(21) Appl. No.: 18/726,432

(22) PCT Filed: Apr. 18, 2023
(86) PCT No.: PCT/CN2023/088931

§ 371 Date: Nov. 26, 2024

(30) Foreign Application Priority Data
Oct. 24, 2022 (CN) 202211298552.6

(51) Int. Cl. G06F 30/33; H04L 69/06; H04L 69/166

(52) U.S. Cl. CPC G06F 30/33; H04L 69/06; H04L 69/166

(57) ABSTRACT

The present disclosure discloses a method and a system for operating a complex data packet capable of being dynamically defined, and relates to the field of chip design and verification, and software technologies. The method includes: constructing a two-dimensional data structure of a data packet based on an actual programming requirement; performing slicing processing on the two-dimensional data structure of the data packet in a slicing manner; selecting an element corresponding to a processed slice from the data packet, and performing a storage and retrieval operation on a data packet element; marking each processed slice based on the processed slice; denoting a marked slice as a segment, and performing an element access operation on the segment in the data packet by using a mark; and comparing different data packets based on marked data packets and segments.

### CROSS-REFERENCE TO RELATED APPLICATION

This application claims the benefit of Chinese Patent Application No. 202211298552.6, filed on Oct. 24, 2022, which is hereby incorporated by reference in its entirety including any tables, figures, or drawings.

### TECHNICAL FIELD

The present disclosure relates to the field of chip design and verification, and software technologies, and specifically, to a method and a system for operating a complex data packet capable of being dynamically defined.

### BACKGROUND

In chip design and verification, and driver software programming, various types of protocol data packets need to be processed. These protocol data packets have many data fields and complex structures. In the communication field, the TCP/IP protocol is used to transfer an IP data packet, the data packet includes a header and a data part, and each part includes a field with a different quantity of bits.

This data packet format is often processed during chip design and verification. Especially during chip verification, this type of data incentive needs to be constructed. When a verification platform is built, a data structure that can be used currently is a struct (struct) with a bit field in the C/C++ language, as shown below:

struct IPHeader
{
unsigned int ver:4;
unsigned int len:4;
unsigned int server:8;
unsigned int total:16;
...
}

When the System Verilog language is used for verification, similarly, only a similar packed struct can be used to construct such a data packet:

struct packaged
{
bit[3:0] ver;
bit[3:0] len;
bit[7:0] server;
bit[15:0] total;
...
}

In the foregoing, generating a data packet by using the struct has the following disadvantages:
1. Bit widths of data fields in the data packet are different, making definition in the struct complex.
2. A struct needs to be defined for each type of data, an amount of definition is large, and the definition cannot be dynamically modified.
3. It is complex to read and assign a value to the data field in the data packet. If a more complex data packet structure is encountered, such as an OTN (Optical Transport Network) frame structure for optical transport, it is extremely complex to construct such a data packet structure. OPUk data fields cross columns and rows. It is difficult to describe such a data structure by using the struct, and it is difficult to access the data fields across rows and columns. The frame structure of the OTN data packet is shown in FIG. 2.

In an example of a two-dimensional array in the System Verilog language, definition of the two-dimensional array looks unnatural, and it is complex to assign a value. When a constant is used to assign a value, braces are used, and a single quotation mark further needs to be used in front of the braces, which increases use costs. A method that can be used is also poor, and cannot implement more powerful functions. Detailed definition and value assignment operations are as follows:

```
//define an 8-row 4-column byte (8 bits) array
byte data1[0:7][0:3]; //complete declaration
        byte data2[8][4]; //more compact declaration
        data2[7][3] = 1; //set a value of an element in the row 8 and the
column 4, namely, the last element
        // assign a value to the two-dimensional array
        int data [2][3] = {{1, 2, 3}, {4, 5, 6}};
```

In a System Verilog simulator, 8-bit data of a byte type needs to be stored by using 32 bits, which consumes a large amount of space. To save space, a packed (packed) array is introduced. During use in this way, the verification engineer needs to pay attention to data storage details, which consumes energy of the engineer.

However, a plurality of structs need to be defined for one data packet, and sizes and shapes of data generated by the structs are different. It is a very complex and difficult programming process to assemble the data generated by the structs.

In summary, common arrays and structs in conventional languages can meet a programming requirement. However, when the verification engineer uses the arrays and the structs, the verification engineer needs to perform very complex processing steps, and needs to undertake a large amount of programming work. As a result, the following problem is caused: Access, use, and maintenance of the data packet are inconvenient, causing large programming workload and low efficiency in chip design and verification processes.

### SUMMARY

A technical problem to be resolved in the present disclosure is the following problem: Because a current complex data packet is based on static definition, and definition is complex and cannot be dynamically modified, access and maintenance of the complex data packet are inconvenient, causing large programming workload and low efficiency in chip design and verification processes. The present disclosure aims to provide a method and a system for operating a complex data packet capable of being dynamically defined. In the present disclosure, a two-dimensional data structure “byte” is designed for features of various data packets, so that definition, use, and maintenance of the data packet are simple and fast, programming workload is greatly reduced, efficiency is improved, and design and verification work requirements of a chip can be met.

The present disclosure is implemented by the following technical solutions:

According to a first aspect, the present disclosure provides a method for operating a complex data packet capable of being dynamically defined, where the method includes:
constructing a two-dimensional data structure of a data packet based on an actual programming requirement, where the two-dimensional data structure of the data packet is a byte-type-based two-dimensional data structure;
performing slicing processing on the two-dimensional data structure of the data packet in a slicing manner, to obtain a processed slice; and
selecting an element corresponding to the processed slice from the data packet based on the processed slice, and performing a storage and retrieval operation on a data packet element.

Further, the byte-type-based two-dimensional data structure is represented as byte B1 (a, b), byte represents a byte type, B1 represents a name of the data packet, a represents a quantity of rows of the data packet, b represents a quantity of columns of the data packet, namely, a quantity of elements per row, and both a and b are greater than or equal to 1. Each element is one byte.

Further, a quantity of elements of the data packet B1 is a*b, and locations of the elements are numbered from 1 in a left-to-right and top-to-bottom manner.

Further, for the byte-type-based two-dimensional data structure, a row size, a column size, and an overall capacity of the two-dimensional data structure are capable of being adjusted based on a byte size.

Further, the slicing manner includes a single-element-based slicing manner, and the single-element-based slicing manner includes selecting a single element in a one-dimensional manner and selecting a single element in a two-dimensional manner;
the single element selected in the one-dimensional manner is represented as [p], and p is a location number of the element selected from the data packet; and
the single element selected in the two-dimensional manner is represented as [r:c], r is a row number of the element selected from the data packet, and c is a column number of the element selected from the data packet.

Further, the slicing manner further includes a multi-element-based slicing manner, and the multi-element-based slicing manner includes a one-dimensional multi-element slicing manner;
the one-dimensional multi-element slicing manner is to select a plurality of elements in the one-dimensional manner, and the plurality of elements selected in the one-dimensional manner are represented as [p1, . . . , p2], p1 is a start number of the elements selected from the data packet, and p2 is an end number of the elements selected from the data packet; and
the plurality of elements selected in the one-dimensional manner are further represented as [p, n], p is a start number of the elements selected from the data packet, and n is a length of the elements selected from the data packet.

Further, the multi-element-based slicing manner further includes an entire-row or entire-column slicing manner; and
an entire row or entire column of elements is selected in the entire-row or entire-column slicing manner, and is represented as [‘T’, t], T is the entire-row or entire-column slicing manner of the data packet, T is row or column, and t is a row number or column number of an element to be selected from the data packet.

Specifically, the entire-row or entire-column slicing manner includes an entire-row slicing manner and an entire-column slicing manner;
an entire row of elements is selected in the entire-row slicing manner, and is represented as [‘row’, r], row is the entire-row slicing manner of the data packet, and r is a row number of the element selected from the data packet; and
an entire column of elements is selected in the entire-column slicing manner, and is represented as [‘column’, c], column is the entire-column slicing manner of the data packet, and c is a column number of the element selected from the data packet.

Further, the multi-element-based slicing manner further includes a row-cross or column-cross slicing manner; and
several elements are selected across rows or columns starting from an element in a specific row and a specific column in the row-cross or column-cross slicing manner, and are represented as [‘I’, r:c, n], I is the row-cross or column-cross slicing manner of the data packet, I is r or c, r:c means starting from an element in a row r and a column c in the data packet, and n is a total quantity of elements selected across rows or columns.

Specifically, the row-cross or column-cross slicing manner includes a row-cross slicing manner and a column-cross slicing manner;
several elements are selected in the row-cross slicing manner, and are represented as [‘r’, r:c, n], r is the row-cross slicing manner of the data packet, r:c means starting from an element in a row r and a column c in the data packet, and n is a total quantity of elements selected across rows; and
several elements are selected in the column-cross slicing manner, and are represented as [‘c’, r:c, n], c is the column-cross slicing manner of the data packet, r:c means starting from an element in a row r and a column c in the data packet, and n is a total quantity of elements selected across columns.

Further, the multi-element-based slicing manner further includes a transverse row-cross or longitudinal column-cross slicing manner; a regular block is selected across rows or columns starting from an element in a specific row and a specific column in the transverse row-cross or longitudinal column-cross slicing manner, and is represented as [‘M’, m, r:c, n], M is the transverse row-cross or longitudinal column-cross slicing manner of the data packet, M is h or v, m is a row change spacing or a column cross spacing, r:c means starting from an element in a row r and a column c in the data packet, and n is a total quantity of elements selected through alignment; and
when m is defaulted, it indicates that a rightmost boundary of a row or a lowermost boundary of a column is reached.

Specifically, the transverse row-cross or longitudinal column-cross slicing manner includes a transverse row-cross slicing manner and a longitudinal column-cross slicing manner;
a regular block is selected across rows or columns starting from an element in a specific row and a specific column in the transverse row-cross slicing manner, and is represented as [‘h’, m1, r:c, n], h is the transverse row-cross slicing manner (namely, transverse selection) of the data packet, m1 is a row change spacing (namely, a quantity of columns crossed transversely during transverse row cross), r:c means starting from an element in a row r and a column c in the data packet, and n is a total quantity of elements selected through alignment by transversely crossing columns to the end of a row; and
a regular block is selected across rows or columns starting from an element in a specific row and a specific column in the longitudinal column-cross slicing manner, and is represented as [‘v’, m2, r:c, n], v is the longitudinal column-cross slicing manner (namely, longitudinal selection) of the data packet, m2 is a column cross spacing (namely, a quantity of rows crossed longitudinally during longitudinal column cross), r:c means starting from an element in a row r and a column c in the data packet, and n is a total quantity of elements selected through alignment by longitudinally crossing rows to the end of a column.

Further, the multi-element-based slicing manner further includes a transverse rectangular or longitudinal rectangular slicing manner; and
a rectangular block is selected across rows and columns starting from an element in a specific row and a specific column in the transverse rectangular or longitudinal rectangular slicing manner, and is represented as [‘N’, r:c, x, y], N is the transverse rectangular or longitudinal rectangular slicing manner of the data packet, r:c means starting from an element in a row r and a column c in the data packet, x is a quantity of elements selected transversely per row, and y is a quantity of elements selected longitudinally per column.

Specifically, the transverse rectangular or the longitudinal rectangular slicing manner includes a transverse rectangular slicing manner and a longitudinal rectangular slicing manner;
a rectangular block is selected across rows and columns starting from an element in a specific row and a specific column in the transverse rectangular slicing manner, and is represented as [‘h’, r:c, x, y], h is the transverse rectangular slicing manner of the data packet, r:c means starting from an element in a row r and a column c in the data packet, x is a quantity of elements selected transversely per row, y is a quantity of elements selected longitudinally per column, and selected bytes are successively arranged from left to right and top to bottom to form an xxy rectangular block; and
a rectangular block is selected across rows and columns starting from an element in a specific row and a specific column in the longitudinal rectangular slicing manner, and is represented as [‘v’, r:c, x, y], v is the longitudinal rectangular slicing manner of the data packet, r:c means starting from an element in a row r and a column c in the data packet, x is a quantity of elements selected transversely per row, y is a quantity of elements selected longitudinally per column, and selected bytes are successively arranged from top to bottom and left to right to form an xxy rectangular block.

Further, the method further includes:
marking each processed slice based on the processed slice to obtain a marked slice; and denoting the marked slice as a segment, and performing an element access operation on the segment in the data packet by using a mark.

Further, the mark includes a primary mark and a secondary mark, the primary mark is of a numerical type, the primary mark is a non-repeating number, the secondary mark is of a string type, and the secondary mark is a non-repeating string; and
the element access operation is performed on the segment in the data packet by using the primary mark and/or the secondary mark.

Further, the method further includes:
comparing different data packets based on marked data packets and segments, and outputting a comparison result. That is, unpacking is not required during data check.

According to a second aspect, the present disclosure further provides a system for operating a complex data packet capable of being dynamically defined, where the system supports the method for operating a complex data packet capable of being dynamically defined, and the system includes:
a construction unit, configured to construct a two-dimensional data structure of a data packet based on an actual programming requirement, where the two-dimensional data structure of the data packet is a byte-type-based two-dimensional data structure;
a slicing processing unit, configured to perform slicing processing on the two-dimensional data structure of the data packet in a slicing manner, to obtain a processed slice; and
a selection and storage and retrieval unit, configured to: select an element corresponding to the processed slice from the data packet based on the processed slice, and perform a storage and retrieval operation on a data packet element.

Compared with the conventional technology, the present disclosure has the following advantages and beneficial effects:
1. According to the method and the system for operating a complex data packet capable of being dynamically defined in the present disclosure, the current data packet is constructed based on the byte-type two-dimensional data structure, so that construction is very simple, and dynamic definition can be implemented. In addition, various consecutive byte data can be selected in 10 types of rich slicing manners, which is very flexible, and facilitates a storage and retrieval operation of a data packet element.
2. According to the method and the system for operating a complex data packet capable of being dynamically defined in the present disclosure, a mark is added to a slice, and the slice is accessed based on the mark, so that coding is simpler and more convenient.
3. According to the method and the system for operating a complex data packet capable of being dynamically defined in the present disclosure, when two complex data packets are compared, only slices with a same mark are compared, so that a programming workload can be reduced, which is simple and efficient.
4. In the present disclosure, when a same data packet generation function is completed, compared with an existing solution, 50% to 80% programming workload can be reduced.

### BRIEF DESCRIPTION OF DRAWINGS

The accompanying drawing described herein is used to provide further understanding of embodiments of the present disclosure, and constitutes a part of the present application, but does not constitute limitations to the embodiments of the present disclosure. In the accompanying drawings:

FIG. 1 is a diagram of a data format of an IP data packet;

FIG. 2 is a schematic diagram of a frame structure of an OTN data packet;

FIG. 3 is a flowchart of a method for operating a complex data packet capable of being dynamically defined according to Embodiment 1 of the present disclosure;

FIG. 4 is a schematic diagram of a byte-type-based two-dimensional data structure according to the present disclosure;

FIG. 5 is a schematic diagram of a value assignment operation of a single-element-based slicing manner according to the present disclosure;

FIG. 6 is a schematic diagram of selection of a one-dimensional multi-element slicing manner according to the present disclosure;

FIG. 7 is a schematic diagram of selection and value assignment of an entire-row slicing manner according to the present disclosure;

FIG. 8 is a schematic diagram of selection and value assignment of an entire-column slicing manner according to the present disclosure;

FIG. 9 is a schematic diagram of selection and value assignment of a row-cross slicing manner according to the present disclosure;

FIG. 10 is a schematic diagram of selection and value assignment of a column-cross slicing manner according to the present disclosure;

FIG. 11 is a schematic diagram of selection and value assignment of a transverse row-cross slicing manner according to the present disclosure;

FIG. 12 is a schematic diagram of selection and value assignment of a longitudinal column-cross slicing manner according to the present disclosure;

FIG. 13 is a schematic diagram of selection of a transverse rectangular slicing manner according to the present disclosure;

FIG. 14 is a schematic diagram of selection of a longitudinal rectangular slicing manner according to the present disclosure;

FIG. 15 is a flowchart of a method for operating a complex data packet capable of being dynamically defined according to Embodiment 2 of the present disclosure;

FIG. 16 is a schematic diagram of an OTN data packet marked with a mark by using step 4 according to the present disclosure;

FIG. 17 is a schematic diagram of constructing B1 and B2 and performing comparison through marking according to the present disclosure; and

FIG. 18 is a schematic structural diagram of a system for operating a complex data packet capable of being dynamically defined according to the present disclosure.

### DESCRIPTION OF EMBODIMENTS

To make the objectives, technical solutions and advantages of the present disclosure clearer, the present disclosure is further described in detail below with reference to embodiments and the accompanying drawing. The schematic implementations of the present disclosure and descriptions thereof are only used to explain the present disclosure, but are not intended to limit the present disclosure.

### Embodiment 1

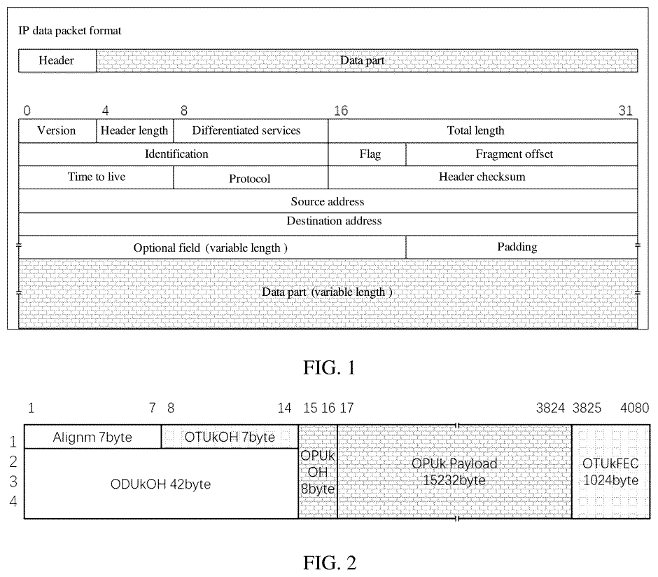

In the field of chip design and verification and in the field of software, generating and processing an IP data packet, a PCIe data packet, and an OTN data packet are very common requirements. An existing programming language on the market is also a programming language used in the field of verification, such as C/C++, System Verilog, and Python languages. No language supports a data structure that can implement these requirements efficiently, and complex programming often needs to be performed to implement these requirements. FIG. 1 is a diagram of a data format of an IP data packet.

Therefore, in the present disclosure, based on a byte-type data structure, a method for operating a complex data packet capable of being dynamically defined is designed to resolve the following problem in a conventional technology: Access and maintenance of a complex data packet are inconvenient, causing large programming workload and low efficiency in chip design and verification processes. A design idea of the present disclosure is as follows: A data packet is considered as a whole instead of a part, and a data packet structure is constructed in a two-dimensional, container, and dynamic manner. When a two-dimensional structure is used as a basis, 10 types of slicing manners are provided, so that consecutive data elements with different shapes and different arrangement directions can be randomly selected, which is convenient and flexible, and adapts to various types of data packet structures.

In the present disclosure, a byte (byte)-type-based two-dimensional data structure is constructed to resolve the following problem in the conventional technology: Access and maintenance of a complex data packet are inconvenient, causing large programming workload and low efficiency in chip design and verification processes. The present disclosure has the following features:
1. Integration: In the present disclosure, a data packet is considered as a whole, and the data packet is not formed by splicing a plurality of pieces of data, because splicing is very difficult and complex. However, a conventional struct considers the data packet as fragment data fields.
2. Two-dimensional: In the present disclosure, a data packet structure is generally described in a two-dimensional manner, which is direct and clear. A new byte data structure corresponds to the two-dimensional manner, and is designed as a two-dimensional structure.
3. Containerization: The byte data type is a two-dimensional container that can contain data with various sizes and shapes.
4. Diversity: Storage and retrieval manners of the byte data type are diversified, and data with a plurality of shapes and sizes can be defined in two-dimensional space.
5. Dynamic: Definition of the data packet structure can be dynamically adjusted, which reduces workload of defining a struct.

As shown in FIG. 3, FIG. 3 is a flowchart of a method for operating a complex data packet capable of being dynamically defined according to Embodiment 1 of the present disclosure. The present disclosure provides a method for operating a complex data packet capable of being dynamically defined. As shown in FIG. 3, the method includes the following steps.

Step 1: Construct a two-dimensional data structure of a data packet based on an actual programming requirement, where the two-dimensional data structure of the data packet is a byte-type-based two-dimensional data structure.

Specifically, the byte-type-based two-dimensional data structure is represented as byte B1 (a, b), byte represents a byte type, B1 represents a name of the data packet, a represents a quantity of rows of the data packet, b represents a quantity of columns of the data packet, namely, a quantity of elements per row, and both a and b are greater than or equal to 1. Each element is one byte. A quantity of elements of the data packet B1 is a*b, and locations of the elements are numbered from 1 in a left-to-right and top-to-bottom manner.

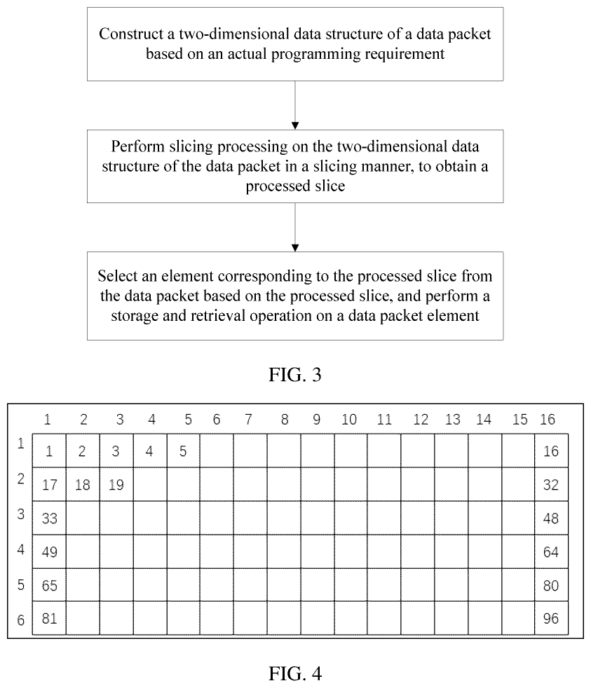

As shown in FIG. 4, FIG. 4 is a schematic diagram of a byte-type-based two-dimensional data structure according to the present disclosure. The data packet is constructed as follows:

byte B1(6, 16)
int size = B1.size( ) // B1 overall size size = 96
int row = B1.row( ) // quantity of rows row = 6
int col = B1.col( ) // quantity of columns col = 16

The foregoing code constructs a two-dimensional variable B1 with six rows and 16 bytes (byte) per row. A size( ) function may be invoked to view a size of the variable. A row( ) function may be invoked to view the quantity of rows. A col( ) function may be invoked to view a quantity of bytes per row.

B1 may be considered as a byte container. Numbers of bytes in the container from left to right and top to bottom are successively 1, 2, 3, . . . , 96. The number starts with 1 instead of 0.

Certainly, another form of construction manner may be used, and is as follows:

byte B1 // one row with 1 byte; byte data has a minimum of 1 byte byte
byte B1(8) // one row with 8 bytes

In a further implementation, for the byte-type-based two-dimensional data structure, a row size, a column size, and an overall capacity of the two-dimensional data structure are capable of being adjusted based on a byte size. Specifically, the byte (byte) size may be adjusted based on a requirement. A resize( ) function can be used to adjust the row size, the column size, and the overall capacity of the two-dimensional data structure. There are three cases of adjusting a capacity of a byte (byte):
1. A size of the capacity remains unchanged, row and column division changes, only a two-dimensional shape of the byte (byte) is changed, and no new storage space is allocated.

int size = B1.size( ) //B1 overall size size = 6 x 16 =96
B1.resize(12, 8) //adjusted B1 overall size size = 12 x 8 = 96

2. When the capacity becomes large, original storage space is not enough to use, new storage space needs to be allocated, and data stored in the old storage space is copied to the new storage space, to release the old storage space. The two-dimensional shape of the byte (byte) is modified synchronously.

B1.resize(6, 32) //adjusted B1 overall size size = 6 x 32 = 192

3. The capacity becomes small, new smaller storage space is allocated, data stored in old storage space is copied to the new storage space, and subsequent data is discarded, to release the old storage space. The two-dimensional shape of the byte (byte) is modified synchronously.

B1.resize(6, 8) //adjusted B1 overall size size = 6 x 8 = 48

If only one row needs to be constructed, the byte (byte) type is a one-dimensional data structure, the one-dimensional data structure is a special case of the two-dimensional data structure, and the two data structures are unified. There are two construction manners of one-dimensional byte (byte), and the two manners are equivalent and are as follows:

```
        byte B1(1, 16)
        byte B1(16) //when the quantity of rows is 1,
the row parameter may be omitted during construction
```

Step 2: Perform slicing processing on the two-dimensional data structure of the data packet in a slicing manner, to obtain a processed slice.

Specifically, the present disclosure includes 10 types of slicing manners:

(1) Single-Element-Based Slicing Manner

The single-element-based slicing manner includes selecting a single element in a one-dimensional manner (using a global index for storage and retrieval) and selecting a single element in a two-dimensional manner (using a row and a column for storage and retrieval);
selecting a single element in a one-dimensional manner (using a global index for storage and retrieval) means considering “byte” as a one-dimensional data structure, the single element selected in the one-dimensional manner is represented as [p], and p is a location number of the element selected from the data packet; and
selecting a single element in a two-dimensional manner (using a row and a column for storage and retrieval) means considering a byte as a two-dimensional data structure, the single element selected in the two-dimensional manner is represented as [r:c], r is a row number of the element selected from the data packet, and c is a column number of the element selected from the data packet.

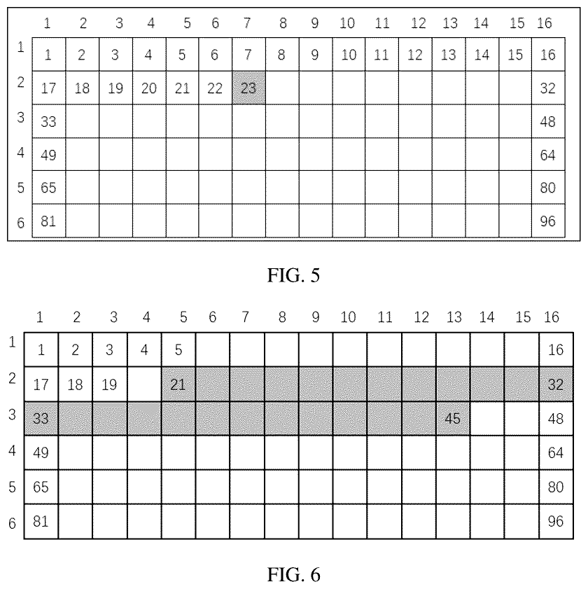

As shown in FIG. 5, FIG. 5 is a schematic diagram of a value assignment operation of a single-element-based slicing manner according to the present disclosure. An example is as follows:

B1[23] = 5 //a byte 23 (namely, an element with a location number
23) is assigned a value 5
B1[2:7] = 5 //a byte in a row 2 and a column 7 (namely, an element with
a location number 23) is assigned a value 5

(2) to (10) are multi-element-based slicing manners, which are specifically as follows:

(2) One-Dimensional Multi-Element Slicing Manner

The one-dimensional multi-element slicing manner is to select a plurality of elements in the one-dimensional manner, and the plurality of elements selected in the one-dimensional manner are represented as [p1, . . . , p2], p1 is a start number of the elements selected from the data packet, and p2 is an end number of the elements selected from the data packet; and
the plurality of elements selected in the one-dimensional manner are further represented as [p,n], p is a start number of the elements selected from the data packet, and n is a length of the elements selected from the data packet. An example is as follows:
b1[21, . . . , 45]
b1[21, 25]

A shaded area in FIG. 6 is an example of slices selected in the one-dimensional multi-element slicing manner.

(3) Entire-Row Slicing Manner

An entire row of elements is selected in the entire-row slicing manner, and is represented as [‘row’, r], row is the entire-row slicing manner of the data packet, r is a row number of the element selected from the data packet, and the selected bytes are successively arranged from left to right.

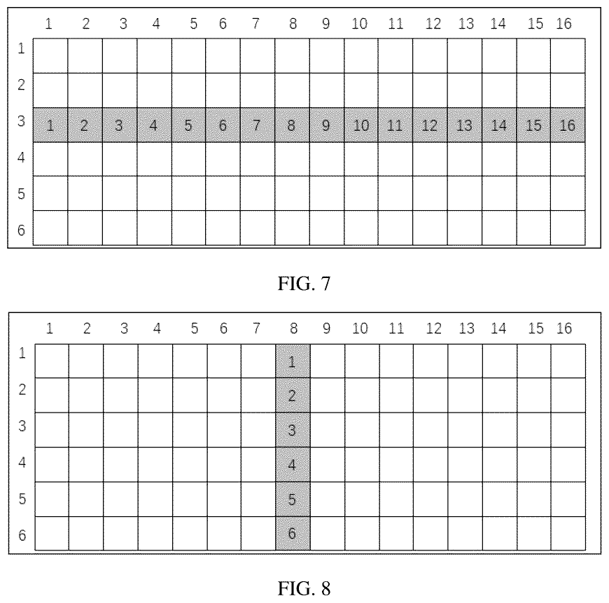

As shown in FIG. 7, for example, for B1 [‘row’, 3],
the statement selects an entire row 3, and selected bytes are successively arranged from left to right.

For byte B2(1, 16)=B1 [‘row’, 3],
the statement assigns elements in the selected entire row 3 to B2.

(4) Entire-Column Slicing Manner

An entire column of elements is selected in the entire-column slicing manner, and is represented as [‘column’, c], column is the entire-column slicing manner of the data packet, and c is a column number of the element selected from the data packet. The selected bytes are successively arranged from top to bottom.

As shown in FIG. 8, for example, for byte B2(1, 6)=B1[‘c’, 8],
the statement assigns elements in a selected entire column 8 to B2.

(5) Row-Cross Slicing Manner

Several elements are selected across rows from an element in a specific row and a specific column in the row-cross slicing manner, and are represented as [‘r’, r:c, n], r is the row-cross slicing manner of the data packet, r:c means starting from an element in a row r and a column c in the data packet, and n is a total quantity of elements selected across rows.

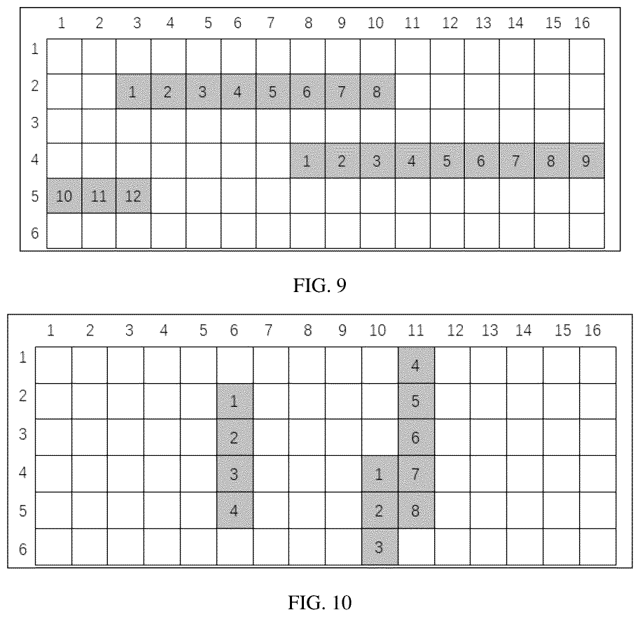

As shown in FIG. 9, for example, for B1[‘r’, 2:3, 8],
the statement selects eight elements starting from an element in a row 2 and a column 3, selected bytes are successively arranged from left to right, and no row change occurs.

For B1 ['r′, 4:8, 12],
the statement selects 12 elements starting from an element in a row 4 and a column 8, selected bytes are successively arranged from left to right and top to bottom, and row change occurs.

For byte B2(1, 8)=B1[‘r’, 2:3, 8],
the statement assigns the eight selected elements starting from the element in the row 2 and the column 3 to B2.

For byte B3 (1, 12) =B1[‘r’, 4:8, 12],
the statement assigns 12 selected elements starting from an element in a row 4 and a column 8 to B3.

(6) Column-Cross Slicing Manner

Several elements are selected across columns starting from an element in a specific row and a specific column in the column-cross slicing manner, and are represented as [‘c’, r:c, n], c is the column-cross slicing manner of the data packet, r:c means starting from an element in a row r and a column c in the data packet, and n is a total quantity of elements selected across columns.

As shown in FIG. 10, for example,
for B1[‘c’, 2:6, 4],
the statement selects four elements starting from an element in a row 2 and a column 6, selected bytes are successively arranged from top to bottom, and no column cross occurs.

For B1[‘c’, 4:10, 8],
the statement selects eight elements starting from an element in a row 4 and a column 10, and selected bytes are successively arranged from top to bottom and left to right across columns.

For byte B2(1, 4)=B1[‘c’, 2:6, 4],
the statement assigns the four selected elements starting from the element in the row 2 and the column 6 to B2.

For byte B3(1, 8)=B1 [‘c’, 4:10, 8],
the statement assigns the eight selected elements starting from the element in the row 4 and the column 10 to B3.

(7) Transverse Row-Cross Slicing Manner

A regular block is selected across rows or columns starting from an element in a specific row and a specific column in the transverse row-cross slicing manner, and is represented as [‘h’, m1, r:c, n], h is the transverse row-cross slicing manner of the data packet, m1 is a row change spacing (namely, a quantity of columns crossed transversely during transverse row cross), r:c means starting from an element in a row r and a column c in the data packet, and n is a total quantity of elements selected through alignment by transversely crossing columns to the end of a row; and when m1 is default, it indicates that a rightmost boundary of a row is reached.

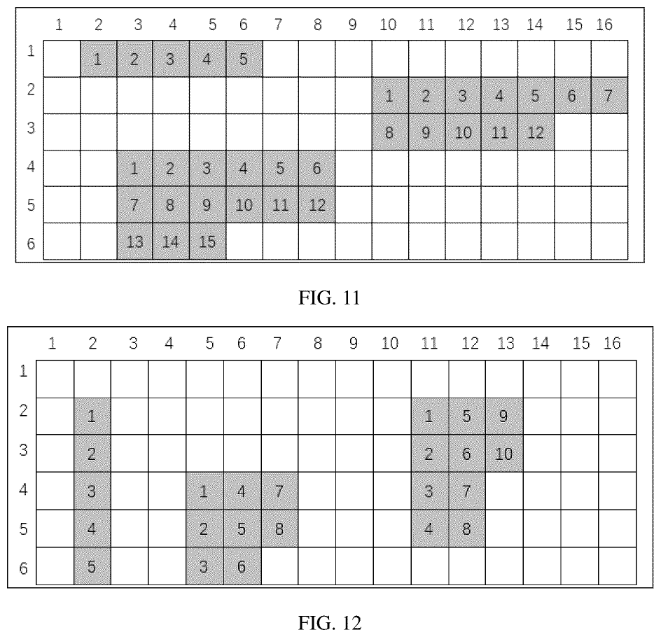

As shown in FIG. 11, for example,
for B1[‘h’, 1:2, 5],
the statement selects five elements starting from an element in a row 1 and a column 2, and ‘h’ represents horizontal (horizontal) selection. Selected bytes are successively arranged from left to right, and no row cross or column cross occurs.

For B1 ['h′, 2:10, 12],

the statement selects 12 elements starting from an element in a row 2 and a column 10, and ‘h’ represents horizontal (horizontal) selection. Selected bytes are arranged from left to right, row change occurs when a rightmost column is reached, and a start column after row change is a column in which the first element is located.

For B1 ['h′, 6, 4:3, 15],
the statement selects 15 elements starting from an element in a row 4 and a column 3, and [‘h’, 6] represents that row change is performed after six elements are horizontally selected. A start column after row change is a column number of the first element.

Corresponding value assignment statements are as follows:

$$byte B 2 ( 1 , 5 ) = B 1 {[}^{‵} {h}^{′} , 1 : 2 , 5 ]$$

$$byte B 3 ( 1 , 12 ) = B 1 {[}^{‵} {h}^{′} , 2 : 10 , 12 ]$$

$$byte B 4 ( 1 , 15 ) = B 1 {[}^{‵} {h}^{′} , 6 , 4 : 3 , 15 ]$$

(8) Longitudinal Column-Cross Slicing Manner

A regular block is selected across rows or columns starting from an element in a specific row and a specific column in the longitudinal column-cross slicing manner, and is represented as [‘v’, m2, r:c, n], v is the longitudinal column-cross slicing manner of the data packet, m2 is a column cross spacing (namely, a quantity of rows crossed longitudinally during longitudinal column cross), r:c means starting from an element in a row r and a column c in the data packet, and n is a total quantity of elements selected through alignment by longitudinally crossing rows to the end of a column; and when m2 is default, it indicates that a lowermost boundary of a column is reached.

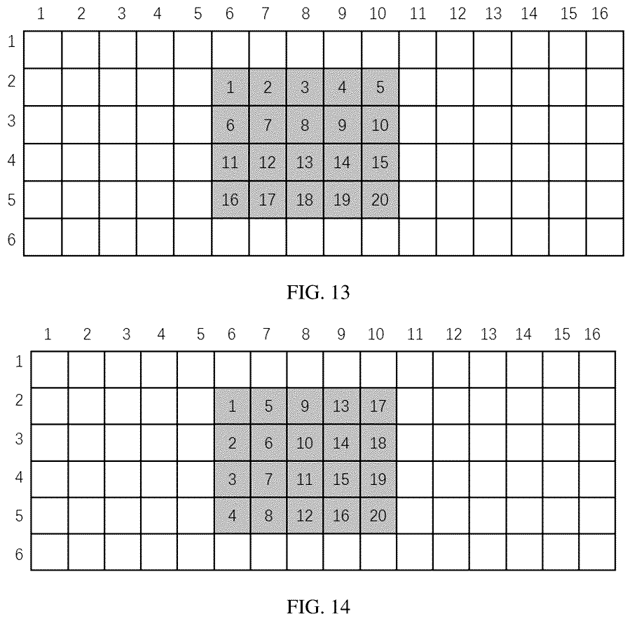

As shown in FIG. 12, for example,

for B1[‘v’, 2:2, 5],
the statement selects five elements starting from an element in a row 2 and a column 2, and ‘v’ represents vertical (vertical) selection. Selected bytes are successively arranged from top to bottom, and no row cross or column cross occurs.

For B1[‘v’, 4:5, 8],
the statement selects eight elements starting from an element in a row 4 and a column 5, and ‘v’ represents (vertical) vertical selection. Selected bytes are arranged from top to bottom, column cross occurs when the last row is reached, and a start row after column cross is a row in which the first element is located.

For B1[‘v’, 4, 2:11, 10],
the statement selects 10 elements starting from an element in a row 2 and a column 11, and [‘v’, 4] represents that column cross is performed after four elements are selected vertically. A start row after column cross is a row in which the first element is located.

Corresponding value assignment statements are as follows:

$$byte B 2 ( 1 , 5 ) = B 1 {[}^{‵} {v}^{′} , 2 : 2 , 5 ]$$

$$byte B 3 ( 1 , 12 ) = B 1 {[}^{‵} {v}^{′} , 4 : 5 , 8 ]$$

$$byte B 4 ( 1 , 15 ) = B 1 {[}^{‵} {v}^{′} , 4 , 2 : 11 , 10 ]$$

(9) Transverse Rectangular Slicing Manner

A rectangular block is selected across rows or columns starting from an element in a specific row and a specific column in the transverse rectangular slicing manner, and is represented as [‘h’, r:c, x, y], h is the transverse rectangular slicing manner of the data packet, r:c means starting from an element in a row r and a column c in the data packet, x is a quantity of elements selected transversely per row, y is a quantity of elements selected longitudinally per column, and selected bytes are successively arranged from left to right and top to bottom to form an xxy rectangular block.

As shown in FIG. 13, for example,
for B1[‘h’, 2:6, 5, 4],
the statement selects five elements transversely and four elements longitudinally from an element in a row 2 and a column 6, and ‘h’ represents horizontal (horizontal) transverse selection. Selected bytes are successively arranged from left to right and top to bottom to form a 5×4 rectangle.

(10) Longitudinal Rectangular Slicing Manner

A rectangular block is selected across rows or columns starting from an element in a specific row and a specific column in the longitudinal rectangular slicing manner, and is represented as [‘v’, r:c, x, y], v is the longitudinal rectangular slicing manner of the data packet, r:c means starting from an element in a row r and a column c in the data packet, x is a quantity of elements selected transversely per row, y is a quantity of elements selected longitudinally per column, and selected bytes are successively arranged from top to bottom and left to right to form an xxy rectangular block.

As shown in FIG. 14, for example,
for B1 ['v′, 2:6, 5, 4],
the statement selects five elements transversely and four elements longitudinally from an element in a row 2 and a column 6, and ‘v’ represents vertical (vertical) selection. Selected bytes are successively arranged from top to bottom and left to right to form a 5×4 rectangle.

This embodiment is implemented by constructing the two-dimensional data structure of the OTN data packet by using the method in the present disclosure. Each block is represented by using a slice, as shown in Table 1:

TABLE 1

| OTN | byte otn(4, 4080) |
|---|---|
| Alignm | otn[‘r’, 1:1, 7] |
| OTUkOH | otn[‘r’, 1:8, 7] |
| ODUkOH | otn[‘h’, 14, 2:1, 42] |
| | otn[‘v’, 3, 2:1, 42] |
| OPUkOH | otn[‘h’, 2, 1:15, 8] |
| | otn[‘v’, 4, 1:15, 8] |
| OPUk | otn[‘h’, 3808, 1:17, 15232] |
| | otn[‘v’, 4, 1:17, 15232] |
| OPUkFEC | otn[‘h’, 1:3825, 1024] |
| | otn[‘h’, 256, 1:3825, 1024] |
| | otn[‘v’, 4, 1:3825, 1024] |

Step 3: Select an element corresponding to the processed slice from the data packet based on the processed slice, and perform a storage and retrieval operation on a data packet element.

In the present disclosure, definition of the data packet is very simple, and dynamic definition can be implemented. In addition, various consecutive byte data can be selected in 10 types of rich slicing manners, which is very flexible, and facilitates a storage and retrieval operation of a data packet element.

### Embodiment 2

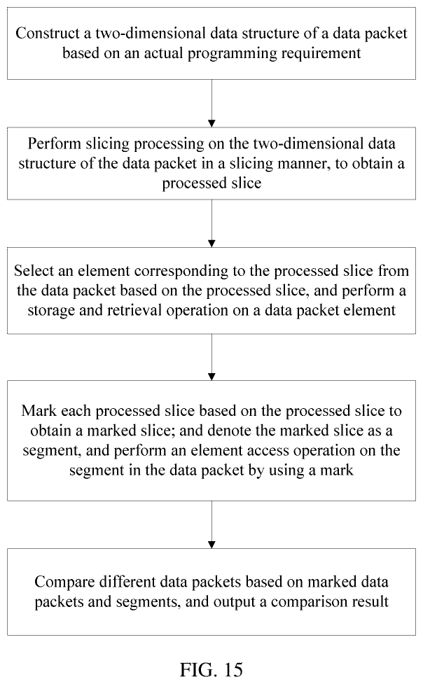

As shown in FIG. 15 to FIG. 17, a difference between this embodiment and Embodiment 1 is as follows: FIG. 15 is a flowchart of a method for operating a complex data packet capable of being dynamically defined according to Embodiment 2 of the present disclosure. The method further includes:

Step 4: Mark each processed slice based on the processed slice to obtain a marked slice; and
denote the marked slice as a segment, and perform an element access operation on the segment in the data packet by using a mark.

In a further implementation, the mark includes a primary mark and a secondary mark, the primary mark is of a numerical type, the primary mark is a non-repeating number, the secondary mark is of a string type, and the secondary mark is a non-repeating string; and
the element access operation is performed on the segment in the data packet by using the primary mark and/or the secondary mark.

In the foregoing technical solution, after the two-dimensional data structure of the data packet is sliced, each slice may be marked with a mark, and the mark includes a primary mark and a secondary mark. The primary mark is a non-repeating number, and the secondary mark is a string and cannot be repeated. The marked slice is named a segment, and the segment is accessed by using the primary mark and the secondary mark, which is simpler and more intuitive than a manner of using the slice.

A mark( ) function is used to mark a slice of the OTN data packet (as shown in FIG. 2) as a segment, and then otn<i> or otn<string> is used to access the segment. Specifically:
mark(int i)
mark (int i, string)

Based on the slice in Table 1, segment access may be performed in the manner in Table 2.

TABLE 2

| Data | | |
|---|---|---|
| segment | Slice mark | Segment access |
| Alignm | otn[‘r’, 1:1, 7].mark(1, “Alignm”) | otn<1> |
| | | otn<“Alignm”> |
| OTUkOH | otn[‘r’, 1:8, 7].mark(2, “OTUkOH”) | otn<2> |
| | | otn<“OTUkOH”> |
| ODUkOH | otn[‘h’, 14, 2:1, 42].mark(3, | otn<3> |
| | “ODUkOH”) | otn<“ODUkOH”> |
| | otn[‘v’, 3, 2:1, 42]. mark(3, | |
| | “ODUkOH”) | |
| OPUkOH | otn[‘h’, 2, 1:15, 8].mark(4, “OPUkOH”) | otn<4> |
| | otn[‘v’, 4, 1:15, 8].mark(4, “OPUkOH”) | otn<“OPUkOH”> |
| OPUk | otn[‘h’, 3808, 1:17, 15232]. mark(5, | otn<5> |
| | “OPUk”) | otn<“OPUk”> |
| | otn[‘v’, 4, 1:17, 15232].mark(5, | |
| | “OPUk”) | |
| OPUkFEC | otn[‘h’, 1:3825, 1024]. mark(6, | otn<6> |
| | “OPUkFEC”) | otn<“OPUkFEC”> |
| | otn[‘h’, 256, 1:3825, 1024].mark(6, | |
| | “OPUkFEC ”) | |
| | otn[‘v’, 4, 1:3825, 1024].mark(6, | |
| | “OPUkFEC”) | |

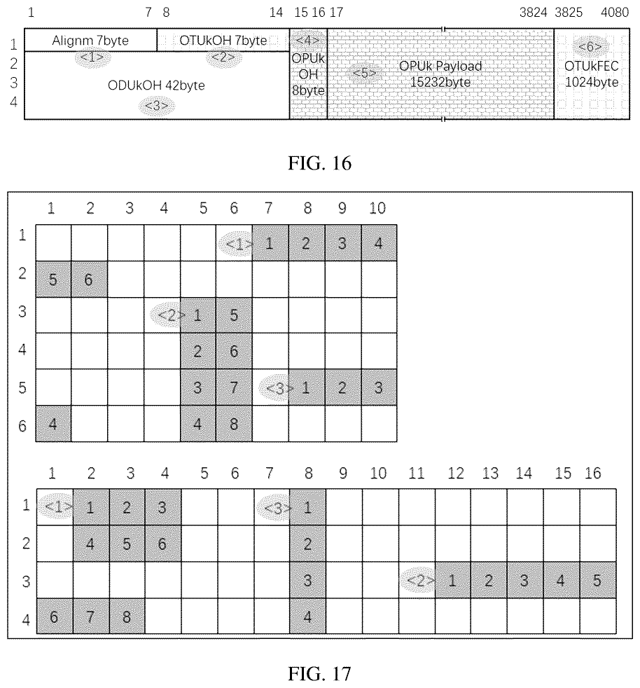

FIG. 16 is a schematic diagram of an OTN data packet marked with a mark by using step 4 in the present disclosure.

In addition, the mark may be cleared, and a clearmarks( ) function is used in software programming to clear the mark. For a byte (byte) object, when the byte object is created, there is a default mark, a primary mark is 1, and a secondary mark is null, which represents the entire byte (byte) object. The clearmarks( ) function is invoked to clear all marks, but the default mark 1 is restored. Access to the segment otn<1> is still valid. A specific statement is as follows:
otn. clearmarks( )
otn<1>

After marking is completed, byte (byte) data and list (list) data can be mutually stored and retrieved. A specific statement is as follows:

$$list < int > 11 = [ 1 , 2 , 3 , 4 , 5 , 6 ]$$

$$list < int > 12$$

$$otn = 11$$

$$12 = otn$$

There are six pieces of data in the foregoing List 11, and values may be assigned to six segments of otn in bulk. List 12 may be used to obtain the values of the six segments of otn in bulk.

In the foregoing technical solution, bulk value assignment and value fetching of a marked slice of a data packet are performed by using a list list.

In a further implementation, the method further includes:

Step 5: Compare different data packets based on marked data packets and segments, and output a comparison result. That is, unpacking is not required during data check.

The byte (byte) type is generally used to generate and transfer a data packet. In a chip verification project, the byte (byte) is first used to generate data packet incentive. One channel of data packet is transferred to a behavioral reference model BRM (Behavioral Reference Model), and an expected result data packet is calculated. After one channel of data packet is processed by using a chip, an actual result data packet is output. A result comparator compares the two types of data packets. When the two types of data packets are compared, it is not necessary to compare all data, only a limited amount of data of interest needs to be compared.

A conventional method is to unpack an overall data packet and extract related data for comparison. This method has no problem in implementation, but the method is complex and consumes a long time.

In the present disclosure, a comparison function is provided for some data of data of the byte (byte) type. Even if two byte data packets have different shapes and sizes, some data can be compared, provided that the slice marking method described in the foregoing section is used.

As shown in FIG. 17, in FIG. 17, a variable B1 of the byte (byte) type of 60 bytes in total with six rows and ten columns, a variable B2 of the byte (byte) type of 64 bytes in total with four rows and sixteen columns are separately constructed, and three segments <1>, <2>, and <3> that have different shapes but a same size are separately marked by using slices. When B1 and B2 are compared, only the three segments are compared. Only when sizes and content of the three corresponding segments are consistent, a comparison result is true. Otherwise, the result is false.

For byte B1 (6, 10),
the statement constructs the variable B1 of the byte (byte) type of 60 bytes in total with six rows and ten columns;
B1['r′, 1:7, 6]. mark(1)
B1['v′, 3:5, 8]. mark(2)
B1['r′, 5:8, 4]. mark(3)

The foregoing three statements are used to slice B1 and perform marking by using a segment.

For byte B2(4, 16),
the statement constructs the variable B2 of the byte (byte) type of 64 bytes in total with four rows and sixteen columns;
B2['h′, 3, 1:2, 6]. mark(1)
B2['r′, 3:12, 8]. mark(2)
B2['c′, 8]. mark(3)

The foregoing three statements are used to slice B2 and perform marking by using a segment.
(B1==B2)

B1 and B2 are compared. If a comparison result is true, B1 and B2 are the same.

In the present disclosure, a mark is added to a slice, and access is performed based on the mark, so that coding is simpler and more convenient. In the present disclosure, when two complex data packets are compared, only slices with a same mark are compared, so that a programming workload can be reduced, which is simple and efficient. In the present disclosure, when a same data packet generation function is completed, compared with an existing solution, 50% to 80% programming workload can be reduced.

### Embodiment 3

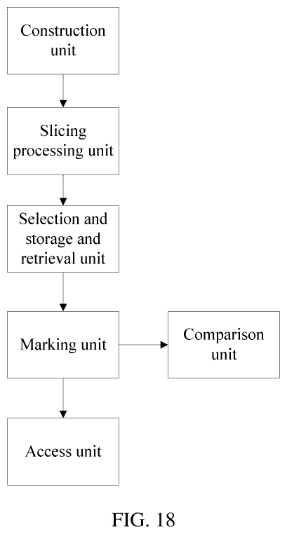

As shown in FIG. 18, a difference between this embodiment and Embodiment 1 is as follows: This embodiment further provides a system for operating a complex data packet capable of being dynamically defined, the system supports the method for operating a complex data packet capable of being dynamically defined in Embodiment 1 or Embodiment 2, and the system includes:
a construction unit, configured to construct a two-dimensional data structure of a data packet based on an actual programming requirement, where the two-dimensional data structure of the data packet is a byte-type-based two-dimensional data structure;
a slicing processing unit, configured to perform slicing processing on the two-dimensional data structure of the data packet in a slicing manner, to obtain a processed slice; and
a selection and storage and retrieval unit, configured to: select an element corresponding to the processed slice from the data packet based on the processed slice, and perform a storage and retrieval operation on a data packet element.

In a further implementation, the system further includes:
a marking unit, configured to mark each processed slice based on the processed slice to obtain a marked slice; and
an access unit, configured to: denote the marked slice as a segment, and perform an element access operation on the segment in the data packet by using a mark.

In a further implementation, the mark includes a primary mark and a secondary mark, the primary mark is of a numerical type, the primary mark is a non-repeating number, the secondary mark is of a string type, and the secondary mark is a non-repeating string; and
the element access operation is performed on the segment in the data packet by using the primary mark and/or the secondary mark.

The system further includes:
a comparison unit, configured to: compare different data packets based on marked data packets and segments, and output a comparison result.

An execution process of each unit is performed based on a procedure step of the method for operating a complex data packet capable of being dynamically defined in Embodiment 1 or Embodiment 2. Details are not described again in this embodiment.

A design idea of the system in the present disclosure is as follows: A data packet is considered as a whole instead of a part, and a data packet structure is constructed in a two-dimensional, container, and dynamic manner. A two-dimensional structure is used as a basis, and 10 types of slicing manners are provided, so that consecutive data with different shapes and different arrangement directions can be randomly selected, which is convenient and flexible, and adapts to various types of data packet structures. In the present disclosure, based on rich slices, a digital and textual mark is added, so that programming is further simple and fast. In addition, it supports bulk value assignment and value fetching of a marked slice of a data packet by using the list list. In addition, in the present disclosure, it supports comparison between some data of two complex data packets based on a mark of a slice, which is simple and efficient.

The objectives, technical solutions, and beneficial effects of the present disclosure are further described in detail in the above specific implementations. It should be understood that the above described are only specific implementations of the present disclosure and are not intended to limit the protection scope of the present disclosure. Any modification, equivalent replacement, improvement, and the like made within the spirit and principle of the present disclosure should fall within the protection scope of the present disclosure.

1. A method for operating a complex data packet capable of being dynamically defined, wherein the method comprising:
constructing a two-dimensional data structure of a data packet based on an actual programming requirement, wherein the two-dimensional data structure of the data packet is a byte-type-based two-dimensional data structure;
performing slicing processing on the two-dimensional data structure of the data packet in a slicing manner, to obtain a processed slice; and
selecting an element corresponding to the processed slice from the data packet based on the processed slice, and performing a storage and retrieval operation on a data packet element.

2. The method for operating a complex data packet capable of being dynamically defined according to claim 1, wherein the byte-type-based two-dimensional data structure is represented as byte B1(a, b), byte represents byte type, B1 represents a name of the data packet, a represents a quantity of rows of the data packet, b represents a quantity of columns of the data packet, namely, a quantity of elements per row, and both a and b are greater than or equal to 1.

3. The method for operating a complex data packet capable of being dynamically defined according to claim 2, wherein a quantity of elements of the data packet B1 is a*b, and locations of the elements are numbered from 1 in a left-to-right and top-to-bottom manner.

4. The method for operating a complex data packet capable of being dynamically defined according to claim 2, wherein for the byte-type-based two-dimensional data structure, a row size, a column size, and an overall capacity of the two-dimensional data structure are capable of being adjusted based on a byte size.

5. The method for operating a complex data packet capable of being dynamically defined according to claim 1, wherein the slicing manner comprises a single-element-based slicing manner, and the single-element-based slicing manner comprises selecting a single element in a one-dimensional manner and selecting a single element in a two-dimensional manner;
the single element selected in the one-dimensional manner is represented as [p], and p is a location number of the element selected from the data packet; and
the single element selected in the two-dimensional manner is represented as [r:c], r is a row number of the element selected from the data packet, and c is a column number of the element selected from the data packet.

6. The method for operating a complex data packet capable of being dynamically defined according to claim 5, wherein the slicing manner further comprises a multi-element-based slicing manner, and the multi-element-based slicing manner comprises a one-dimensional multi-element slicing manner;
the one-dimensional multi-element slicing manner is to select a plurality of elements in the one-dimensional manner, and the plurality of elements selected in the one-dimensional manner are represented as [p1, . . . , p2], p1 is a start number of the elements selected from the data packet, and p2 is an end number of the elements selected from the data packet; and
the plurality of elements selected in the one-dimensional manner are further represented as [p, n], p is a start number of the elements selected from the data packet, and n is a length of the elements selected from the data packet.

7. The method for operating a complex data packet capable of being dynamically defined according to claim 6, wherein the multi-element-based slicing manner further comprises an entire-row or entire-column slicing manner; and
an entire row or entire column of elements is selected in the entire-row or entire-column slicing manner, and is represented as [‘T’, t], T is the entire-row or entire-column slicing manner of the data packet, and t is a row number or column number of the elements selected from the data packet.

8. The method for operating a complex data packet capable of being dynamically defined according to claim 6, wherein the multi-element-based slicing manner further comprises a row-cross or column-cross slicing manner; and
several elements are selected across rows or columns starting from an element in a specific row and a specific column in the row-cross or column-cross slicing manner, and are represented as [‘I’, r:c, n], I is the row-cross or column-cross slicing manner of the data packet, r:c means starting from an element in a row r and a column c in the data packet, and n is a total quantity of elements selected across rows or columns.

9. The method for operating a complex data packet capable of being dynamically defined according to claim 6, wherein the multi-element-based slicing manner further comprises a transverse row-cross or longitudinal column-cross slicing manner;
a regular block is selected across rows or columns starting from an element in a specific row and a specific column in the transverse row-cross or longitudinal column-cross slicing manner, and is represented as [‘M’, m, r:c, n], M is the transverse row-cross or longitudinal column-cross slicing manner of the data packet, m is a row change spacing or a column cross spacing, r:c means starting from an element in a row r and a column c in the data packet, and n is a total quantity of elements selected through alignment; and
when m is defaulted, it indicates that a rightmost boundary of a row or a lowermost boundary of a column is reached.

10. The method for operating a complex data packet capable of being dynamically defined according to claim 6, wherein the multi-element-based slicing manner further comprises a transverse rectangular or longitudinal rectangular slicing manner; and
a rectangular block is selected across rows and columns starting from an element in a specific row and a specific column in the transverse rectangular or longitudinal rectangular slicing manner, and is represented as [‘N’, r:c, x, y], N is the transverse rectangular or longitudinal rectangular slicing manner of the data packet, r:c means starting from an element in a row r and a column c in the data packet, x is a quantity of elements selected transversely per row, and y is a quantity of elements selected longitudinally per column.

11. The method for operating a complex data packet capable of being dynamically defined according to claim 1, wherein the method further comprises:
marking each processed slice based on the processed slice to obtain a marked slice; and
denoting the marked slice as a segment, and performing an element access operation on the segment in the data packet by using a mark.

12. The method for operating a complex data packet capable of being dynamically defined according to claim 11, wherein
the mark comprises a primary mark and a secondary mark, the primary mark is of a numerical type, the primary mark is a non-repeating number, the secondary mark is of a string type, and the secondary mark is a non-repeating string; and
the element access operation is performed on the segment in the data packet by using the primary mark and/or the secondary mark.

13. The method for operating a complex data packet capable of being dynamically defined according to claim 11, wherein the method further comprises:
comparing different data packets based on marked data packets and segments, and outputting a comparison result.

14. A system for operating a complex data packet capable of being dynamically defined, wherein the system supports the method for operating a complex data packet capable of being dynamically defined according to claim 1, and the system comprises:
a construction unit, configured to construct a two-dimensional data structure of a data packet based on an actual programming requirement, wherein the two-dimensional data structure of the data packet is a byte-type-based two-dimensional data structure;
a slicing processing unit, configured to perform slicing processing on the two-dimensional data structure of the data packet in a slicing manner, to obtain a processed slice; and
a selection and storage and retrieval unit, configured to: select an element corresponding to the processed slice from the data packet based on the processed slice, and perform a storage and retrieval operation on a data packet element.

15. The system for operating a complex data packet capable of being dynamically defined according to claim 14, wherein the byte-type-based two-dimensional data structure is represented as byte B1(a, b), byte represents byte type, B1 represents a name of the data packet, a represents a quantity of rows of the data packet, b represents a quantity of columns of the data packet, namely, a quantity of elements per row, and both a and b are greater than or equal to 1.

16. The system for operating a complex data packet capable of being dynamically defined according to claim 15, wherein a quantity of elements of the data packet B1 is a*b, and locations of the elements are numbered from 1 in a left-to-right and top-to-bottom manner.

17. The system for operating a complex data packet capable of being dynamically defined according to claim 14, wherein the slicing manner comprises a single-element-based slicing manner, and the single-element-based slicing manner comprises selecting a single element in a one-dimensional manner and selecting a single element in a two-dimensional manner;
the single element selected in the one-dimensional manner is represented as [p], and p is a location number of the element selected from the data packet; and
the single element selected in the two-dimensional manner is represented as [r:c], r is a row number of the element selected from the data packet, and c is a column number of the element selected from the data packet.

18. The system for operating a complex data packet capable of being dynamically defined according to claim 14, wherein the system further comprises:
a marking unit, configured to mark each processed slice based on the processed slice to obtain a marked slice; and
an access unit, configured to: denote the marked slice as a segment, and perform an element access operation on the segment in the data packet by using a mark.

19. The system for operating a complex data packet capable of being dynamically defined according to claim 18, wherein
the mark comprises a primary mark and a secondary mark, the primary mark is of a numerical type, the primary mark is a non-repeating number, the secondary mark is of a string type, and the secondary mark is a non-repeating string; and
the element access operation is performed on the segment in the data packet by using the primary mark and/or the secondary mark.

20. The system for operating a complex data packet capable of being dynamically defined according to claim 18, wherein the system further comprises:
a comparison unit, configured to: compare different data packets based on marked data packets and segments, and output a comparison result.
